(19) United States
(12) Patent Application Publication
(10) Pub. No.: US 2023/0267358 A1
(43) Pub. Date: Aug. 24, 2023

(54) Distributed Quantum Computing Simulation Method and Apparatus

(71) Applicant: SUZHOU INSPUR INTELLIGENT TECHNOLOGY CP., LTD., Jiangsu (CN)

(72) Inventors: Xin ZHANG, Jiangsu (CN); Yaqian ZHAO, Jiangsu (CN); Rengang LI, Jiangsu (CN); Jinzhe JIANG, Jiangsu (CN); Chen LI, Jiangsu (CN)

(21) Appl. No.: 18/012,528

(22) PCT Filed: Jun. 29, 2021
(86) PCT No.: PCT/CN2021/103305

§ 371 Date: Dec. 22, 2022

(30) Foreign Application Priority Data
Sep. 4, 2020 (CN) 202010923077.1

(51) Int. Cl. G06N 10/20; G06N 10/80; G06N 3/126

(52) U.S. Cl. CPC G06N 10/20; G06N 3/126; G06N 10/80

(57) ABSTRACT

A distributed quantum computing simulation method and apparatus. The method includes: converting a quantum circuit to be simulated into a tensor network that is represented by an undirected graph, and segmenting the undirected graph into a plurality of sub-graphs by using a genetic algorithm that is based on operation resources of a distributed system; respectively performing, on sub-process nodes, tensor contraction and merging on the plurality of sub-graphs for connected tensors until only one tensor is left to finally obtain zero-order tensors of the plurality of sub-graphs at the same time; and acquiring and superposing the zero-order tensors of the plurality of sub-graphs from the sub-process nodes at the same time to determine a zero-order tensor of the undirected graph, and using the zero-order tensor of the undirected graph as a probability amplitude of a positive operator value measurement element, so as to perform quantum computing simulation.

### CROSS-REFERENCE TO RELATED APPLICATION

The present application claims the priority of Chinese Patent Application 202010923077.1, filed in the State Intellectual Property Office of China on Sep. 04, 2020, and entitled “Distributed Quantum Computing Simulation Method and Apparatus”, the entire contents of which are herein incorporated by reference.

### TECHNICAL FIELD

The present invention relates to the field of quantum computing, and in particular, to a distributed quantum computing simulation method and apparatus.

### BACKGROUND

Quantum computing is a novel computing mode using the principles of quantum entanglement and state superposition, which may bring powerful quantum parallelism, and bring a new solution to the problem of insufficient computing power in the Post-Moore era. In practice, for the problem of an exponential increase in the memory overheads of a classical computer simulation quantum system, Feynman has put forward the concept of quantum computing decades ago. After decades of development, quantum computing has made great progress in both hardware and algorithm, especially with Google claiming to realize “quantum hegemony”, quantum computing has come into the public view. However, as a whole, quantum computing is still in a primary stage, and there is still a long way to go before large-scale fault-tolerant quantum computers are implemented. In this context, it is of great significance to construct a quantum computing simulation platform based on a classical computer: (1) it may provide a verification platform for a quantum algorithm, and may also verify the reliability of quantum software and quantum fault tolerance; and (2) it helps understand the boundary between classical computing and quantum computing, and promote the development of quantum computing field.

The construction of the quantum computing simulation platform is a relatively new direction, and there are a full-amplitude mode and a single-amplitude mode at present. In the full-amplitude mode, all amplitudes of a quantum state need to be stored, the amplitudes are regulated and controlled by a quantum gate, a vector dimension required for storing the amplitude of one N quantum bit is 2N, the storage requirement is increased along with the increase index of the quantum bit, and even if one large-scale supercomputer is difficult to simulate a quantum system exceeding 45 quantum bits. Recently, a great progress has also been made in full-amplitude simulation, for example, partial amplitude simulation, and double-bit-gate decomposition. The MPS (Matrix Product State, matrix product state) and PEPS (Projective Entangled Pair States, projective entangled pair states) technologies based on quantum states of associated electronic systems also belong to full-amplitude simulation. These new techniques may enable the scale of full-amplitude simulation to break through 45 quantum bits.

Single-amplitude simulation is a recently developed strategy, in which there is no need to store all amplitudes of the quantum state, and it is only necessary to compute a probability amplitude of a POVM (Positive Operator Value Measurement, positive operator value measurement) element. It is very easy for a single-amplitude strategy to simulate a quantum supremacy circuit and even a shallow quantum circuit exceeding 100 quantum bits. In the single-amplitude mode, a quantum circuit is generally mapped to a tensor network, and a zero-order tensor obtained by contraction and merging is the required probability amplitude. At present, there are two strategies based on path integral and density matrix, and there are relatively many researches based on the path integral strategy. At present, a quantum supremacy circuit capable of simulating 40 layers of 9*9 quantum bits is the best result.

However, for a density matrix-based quantum computing simulation strategy, there are no specific and feasible solutions at home and abroad for running on a distributed supercomputer, and there is only a multi-thread supporting solution, which runs on a plurality of cores in a processor. In view of the problem in the prior art that density matrix-based single-amplitude strategy quantum computing simulation does not support a distributed computing system, there is still no effective solution at present.

### SUMMARY

In view of this, the objective of the embodiments of the present invention is to provide a distributed quantum computing simulation method and apparatus, which may perform density matrix-based single-amplitude strategy quantum computing simulation on a distributed computing system, thereby improving the universality and usability of single-amplitude strategy quantum computing simulation.

Based on the above objective, a first aspect of the embodiments of the present invention provides a distributed quantum computing simulation method, including the following steps:
converting a quantum circuit to be simulated into a tensor network that is represented by an undirected graph, and segmenting the undirected graph into a plurality of sub-graphs by using a genetic algorithm that is based on operation resources of a distributed system;
respectively performing, on sub-process nodes, tensor contraction and merging on the plurality of sub-graphs for connected tensors until only one tensor is left, so as to finally obtain zero-order tensors of the plurality of sub-graphs at the same time; and
acquiring and superposing the zero-order tensors of the plurality of sub-graphs from the sub-process nodes at the same time, so as to determine a zero-order tensor of the undirected graph, and using the zero-order tensor of the undirected graph as a probability amplitude of a positive operator value measurement element, so as to perform quantum computing simulation.

In some embodiments, the step of converting the quantum circuit to be simulated into the tensor network that is represented by the undirected graph, includes:
converting, by using an trace operation, an input state, an operation gate and a measurement of a quantum bit in the quantum circuit into tensors, and determining the tensors to be vertexes in the undirected graph; and
determining connection relationships among the input state, the operation gate and the measurement of the quantum bit in the quantum circuit to be connected edges between corresponding vertices in the undirected graph.

In some implementations, the step of segmenting the undirected graph into the plurality of sub-graphs by using the genetic algorithm that is based on the operation resources of the distributed system, includes:
determining, on the basis of the operation resources of the distributed system, the number of times for segmenting the undirected graph, such that the exponential power of the number of times for segmentation with 4 as a base approaches to the number of available sub-processes;
determining, on the basis of the number of times for segmentation and by using the genetic algorithm, an edge set for segmenting the undirected graph;
cutting an edge in the edge set from the undirected graph, and generating two new vertices at the cut-off position;
assigning one of 4-component density operators {|0><0|, |0><1|, |1><0|, |1><1|} to the two new vertices as the tensors of the two new vertices; and
generating, on the basis of different assignments of the density operators of the tensors of the two new vertices, all possible combinations as the plurality of sub-graphs, wherein the number of sub-graphs is the exponential power of the number of times for segmentation with 4 as the base.

In some embodiments, the step of determining, on the basis of the number of times for segmentation and by using the genetic algorithm, the edge set for segmenting the undirected graph, includes:
constructing a determined number of undirected graphs as individuals to form an undirected graph population, randomly selecting, from the undirected graphs, edges in the number of times for segmentation, so as to generate the edge set, and the following steps are further included:
computing the widths of undirected graph trees of all individuals in the population, and sorting all individuals according to the size of the widths of the undirected graph trees;
enabling all individuals, except the individual with the minimum width of the undirected graph tree, to exchange some edges in the edge set in a two-by-two adjacent manner, so as to perform chromosome variation;
replacing one edge randomly selected from an edge set, which is randomly selected from all individuals except the individual with the minimum width of the undirected graph tree, with another randomly selected edge, so as to perform gene mutation;
in response to the occurrence of repeated edges in the edge set, randomly selecting edges, which do not exist in the edge set, so as to replace the repeated edges; and
repeatedly and circularly performing the steps until the number of cycles exceeds a predetermined maximum number of iterations, and returning optimal individuals in the population as the edge set.

In some implementations, the step of computing the width of the undirected graph tree, includes:
performing tree decomposition on the undirected graph on the basis of all different tension contraction and merging sequences, so as to obtain a plurality of trees;
respectively determining decomposition widths of the corresponding trees on the basis of respective structures of the plurality of trees; and
determining the width of the undirected graph tree on the basis of a minimum value of the decomposition widths of the plurality of trees.

In some embodiments, the step of respectively performing, on the sub-process nodes, tensor contraction and merging on the plurality of sub-graphs for the connected tensors until only one tensor is left, so as to finally obtain the zero-order tensors of the plurality of sub-graphs at the same time, includes: respectively performing, by the sub-process nodes, tensor contraction and merging for different nodes in the plurality of sub-graphs in sequence by using the same tensor contraction and merging sequence, consuming the same computing resources within a unit computing time, and enabling the sub-process nodes with the same computing capability to obtain the zero-order tensors of the plurality of sub-graphs at the same time.

In some embodiments, the step of converting the quantum circuit to be simulated into the tensor network that is represented by the undirected graph, and segmenting the undirected graph into the plurality of sub-graphs by using the genetic algorithm that is based on the operation resources of the distributed system; and the step of acquiring and superposing the zero-order tensors of the plurality of sub-graphs from the sub-process nodes at the same time, so as to determine the zero-order tensor of the undirected graph, and using the zero-order tensor of the undirected graph as the probability amplitude of the positive operator value measurement element, so as to perform quantum computing simulation, are all performed on a main process node of the distributed system.

Based on the above objectives, a second aspect of the embodiments of the present invention provides a distributed quantum computing simulation apparatus, including a main process node and a plurality of sub-process nodes, wherein:
the main process node is configured to convert a quantum circuit to be simulated into a tensor network that is represented by an undirected graph, and segment the undirected graph into a plurality of sub-graphs by using a genetic algorithm that is based on operation resources of a distributed system;
the plurality of sub-process nodes are configured to respectively perform tensor contraction and merging on the plurality of sub-graphs for connected tensors until only one tensor is left, so as to finally obtain zero-order tensors of the plurality of sub-graphs at the same time; and
the main process node is further configured to acquire and superpose the zero-order tensors of the plurality of sub-graphs at the same time, so as to determine a zero-order tensor of the undirected graph, and use the zero-order tensor of the undirected graph as a probability amplitude of a positive operator value measurement element, so as to perform quantum computing simulation.

In some embodiments, the main process node segmenting the undirected graph into the plurality of sub-graphs by using the genetic algorithm that is based on the operation resources of the distributed system includes:
determining, on the basis of the operation resources of the distributed system, the number of times for segmenting the undirected graph, such that the exponential power of the number of times for segmentation with 4 as a base approaches to the number of available sub-processes;
determining, on the basis of the number of times for segmentation and by using the genetic algorithm, an edge set for segmenting the undirected graph;
cutting an edge in the edge set from the undirected graph, and generating two new vertices at the cut-off position;
assigning one of 4-component density operators {|0><0|, |0><1|, |1><0|, |1><1|} to the two new vertices as the tensors of the two new vertices; and
generating, on the basis of different assignments of the density operators of the tensors of the two new vertices, all possible combinations as the plurality of sub-graphs, wherein the number of sub-graphs is the exponential power of the number of times for segmentation with 4 as the base.

In some embodiments, the main process node determining, on the basis of the number of times for segmentation and by using the genetic algorithm, the edge set for segmenting the undirected graph includes:
constructing a determined number of undirected graphs as individuals to form an undirected graph population, randomly selecting, from the undirected graphs, edges in the number of times for segmentation, so as to generate the edge set, and the following steps are further included:
   computing the widths of undirected graph trees of all individuals in the population, and sorting all individuals according to the size of the widths of the undirected graph trees;
   enabling all individuals, except the individual with the minimum width of the undirected graph tree, to exchange some edges in the edge set in a two-by-two adjacent manner, so as to perform chromosome variation;
   replacing one edge randomly selected from an edge set, which is randomly selected from all individuals except the individual with the minimum width of the undirected graph tree, with another randomly selected edge, so as to perform gene mutation;
   in response to the occurrence of repeated edges in the edge set, randomly selecting edges, which do not exist in the edge set, so as to replace the repeated edges; and
   repeatedly and circularly performing the steps until the number of cycles exceeds a predetermined maximum number of iterations, and returning optimal individuals in the population as the edge set.

The present invention has the following beneficial technical effects: according to the distributed quantum computing simulation method and apparatus provided in the embodiments of the present invention, by means of the technical solutions of converting the quantum circuit to be simulated into the tensor network that is represented by the undirected graph, and segmenting the undirected graph into the plurality of sub-graphs by using the genetic algorithm that is based on the operation resources of the distributed system; respectively performing, on the sub-process nodes, tensor contraction and merging on the plurality of sub-graphs for the connected tensors until only one tensor is left, so as to finally obtain the zero-order tensors of the plurality of sub-graphs at the same time; and acquiring and superposing the zero-order tensors of the plurality of sub-graphs from the sub-process nodes at the same time, so as to determine the zero-order tensor of the undirected graph, and using the zero-order tensor of the undirected graph as the probability amplitude of the positive operator value measurement element, so as to perform quantum computing simulation, density matrix-based single-amplitude strategy quantum computing simulation can be performed on a distributed computing system, thereby improving the universality and usability of single-amplitude strategy quantum computing simulation.

### BRIEF DESCRIPTION OF THE DRAWINGS

To illustrate technical solutions in the embodiments of the present invention or in the prior art more clearly, a brief introduction on the drawings which are needed in the description of the embodiments or the prior art is given below. Apparently, the drawings in the description below are merely some of the embodiments of the present invention, based on which other drawings may be obtained by those ordinary skilled in the art without any creative effort.

FIG. 1 is a schematic flow diagram of a distributed quantum computing simulation method provided in the present invention;

FIG. 2 is a quantum circuit diagram of a distributed quantum computing simulation method provided in the present invention;

FIG. 3 is an undirected graph of a distributed quantum computing simulation method provided in the present invention;

FIG. 4 is a schematic diagram of tensor contraction and merging of a distributed quantum computing simulation method provided in the present invention;

FIG. 5 is an edge-cutting diagram of a tensor network of a distributed quantum computing simulation method provided in the present invention.

### DETAILED DESCRIPTION OF THE EMBODIMENTS

In order to make the objectives, technical solutions and advantages of the present invention clearer, the embodiments of the present invention will be further described in detail below in combination with specific embodiments and with reference to the drawings.

It should be noted that, all expressions using “first” and “second” in the embodiments of the present invention are to distinguish two different entities or different parameters of the same name. Therefore, “first” and “second” are only for the convenience of expression, and should not be construed as limitations to the embodiments of the present invention, which will not be illustrated in subsequent embodiments one by one.

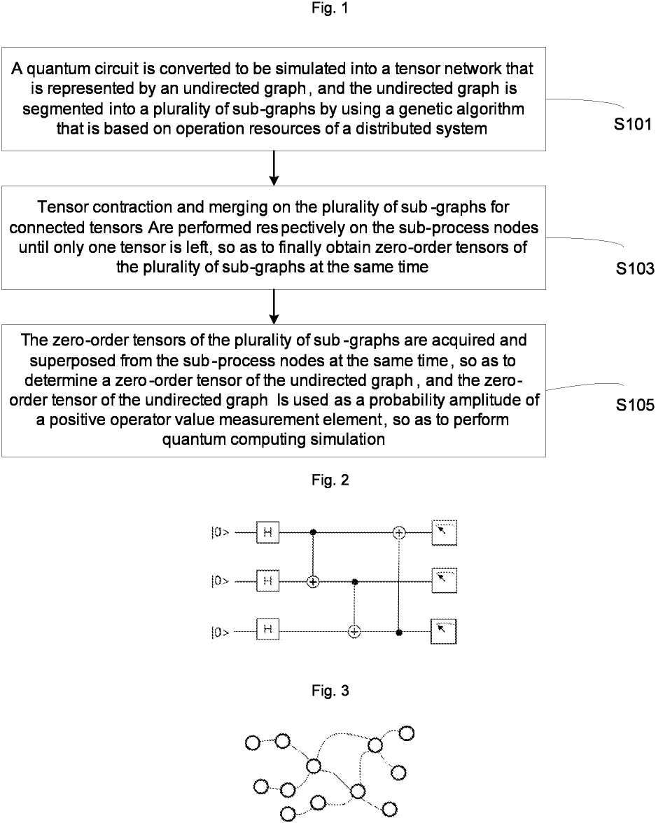

Based on the above objectives, a first aspect of the embodiments of the present invention provides an embodiment of a distributed quantum computing simulation method, which is capable of performing density matrix-based single-amplitude strategy quantum computing simulation on a distributed computing system. FIG. 1 shows a schematic flow diagram of a distributed quantum computing simulation method provided in the present invention.

The distributed quantum computing simulation method, as shown in FIG. 1, includes the following steps:
step S101: converting a quantum circuit to be simulated into a tensor network that is represented by an undirected graph, and segmenting the undirected graph into a plurality of sub-graphs by using a genetic algorithm that is based on operation resources of a distributed system;
step S103: respectively performing, on sub-process nodes, tensor contraction and merging on the plurality of sub-graphs for connected tensors until only one tensor is left, so as to finally obtain zero-order tensors of the plurality of sub-graphs at the same time; and
step S105: acquiring and superposing the zero-order tensors of the plurality of sub-graphs from the sub-process nodes at the same time, so as to determine a zero-order tensor of the undirected graph, and using the zero-order tensor of the undirected graph as a probability amplitude of a positive operator value measurement element, so as to perform quantum computing simulation converting a quantum circuit to be simulated into a tensor network that is represented by an undirected graph, and segmenting the undirected graph into a plurality of sub-graphs by using a genetic algorithm based on operation resources of the distributed system;

Those ordinary skilled in the art may understand that all or some processes in the embodiments of the method described above may be implemented by instructing relevant hardware by means of a computer program, the program may be stored in a computer-readable storage medium, and when executed, the program may include the processes of the embodiments of the methods described above. The storage medium may be a magnetic disk, an optical disk, a read-only storage memory (ROM), or a random storage memory (RAM), etc. The embodiments of the computer program may achieve the same or similar effects as any of the foregoing method embodiments corresponding thereto.

In some embodiments, the step of converting the quantum circuit to be simulated into the tensor network that is represented by the undirected graph, includes:
converting, by using an trace operation, an input state, an operation gate and a measurement of a quantum bit in the quantum circuit into tensors, and determining the tensors to be vertexes in the undirected graph; and
determining connection relationships among the input state, the operation gate and the measurement of the quantum bit in the quantum circuit to be connected edges between corresponding vertices in the undirected graph.

In some implementations, the step of segmenting the undirected graph into the plurality of sub-graphs by using the genetic algorithm that is based on the operation resources of the distributed system, includes:
determining, on the basis of the operation resources of the distributed system, the number of times for segmenting the undirected graph, such that the exponential power of the number of times for segmentation with 4 as a base approaches to the number of available sub-processes;
determining, on the basis of the number of times for segmentation and by using the genetic algorithm, an edge set for segmenting the undirected graph;
cutting an edge in the edge set from the undirected graph, and generating two new vertices at the cut-off position;
assigning one of 4-component density operators {|0><0|, |0><1|, |1><0|, |1><1|} to the two new vertices as the tensors of the two new vertices; and
generating, on the basis of different assignments of the density operators of the tensors of the two new vertices, all possible combinations as the plurality of sub-graphs, wherein the number of sub-graphs is the exponential power of the number of times for segmentation with 4 as the base.

In some embodiments, the step of determining, on the basis of the number of times for segmentation and by using the genetic algorithm, the edge set for segmenting the undirected graph, includes:
constructing a determined number of undirected graphs as individuals to form an undirected graph population, randomly selecting, from the undirected graphs, edges in the number of times for segmentation, so as to generate the edge set, and the following steps are further included:
   computing the widths of undirected graph trees of all individuals in the population, and sorting all individuals according to the size of the widths of the undirected graph trees;
   enabling all individuals, except the individual with the minimum width of the undirected graph tree, to exchange some edges in the edge set in a two-by-two adjacent manner, so as to perform chromosome variation;
   replacing one edge randomly selected from an edge set, which is randomly selected from all individuals except the individual with the minimum width of the undirected graph tree, with another randomly selected edge, so as to perform gene mutation;
   in response to the occurrence of repeated edges in the edge set, randomly selecting edges, which do not exist in the edge set, so as to replace the repeated edges; and
   repeatedly and circularly performing the steps until the number of cycles exceeds a predetermined maximum number of iterations, and returning optimal individuals in the population as the edge set.

In some implementations, the step of computing the width of the undirected graph tree, includes:
performing tree decomposition on the undirected graph on the basis of all different tension contraction and merging sequences, so as to obtain a plurality of trees;
respectively determining decomposition widths of the corresponding trees on the basis of respective structures of the plurality of trees; and
determining the width of the undirected graph tree on the basis of a minimum value of the decomposition widths of the plurality of trees.

In some embodiments, the step of respectively performing, on the sub-process nodes, tensor contraction and merging on the plurality of sub-graphs for the connected tensors until only one tensor is left, so as to finally obtain the zero-order tensors of the plurality of sub-graphs at the same time, includes: respectively performing, by the sub-process nodes, tensor contraction and merging for different nodes in the plurality of sub-graphs in sequence by using the same tensor contraction and merging sequence, consuming the same computing resources within a unit computing time, and enabling the sub-process nodes with the same computing capability to obtain the zero-order tensors of the plurality of sub-graphs at the same time.

In some embodiments, the step of converting the quantum circuit to be simulated into the tensor network that is represented by the undirected graph, and segmenting the undirected graph into the plurality of sub-graphs by using the genetic algorithm that is based on the operation resources of the distributed system; and the step of acquiring and superposing the zero-order tensors of the plurality of sub-graphs from the sub-process nodes at the same time, so as to determine the zero-order tensor of the undirected graph, and using the zero-order tensor of the undirected graph as the probability amplitude of the positive operator value measurement element, so as to perform quantum computing simulation, are all performed on a main process node of the distributed system.

The specific embodiments of the present invention will be further described below according to specific embodiments.

A tensor network is formed by connecting different tensors via topology, and may be generally represented by an undirected graph, and we define the tensor network to be G=(V,E), wherein V is a vertex set, and E is an edge set. For example, a quantum circuit as shown in FIG. 2 corresponds to a tensor network as shown in FIG. 3, and the construction of the corresponding tensor network according to the quantum circuit is a first step for implementing contraction and merging of the tensor network. Each operation gate, each input state and each measurement in the quantum circuit in FIG. 2 correspond to the vertexes in the undirected graph in FIG. 3, and an edge of the quantum circuit corresponds to an edge of the undirected graph.

A tensor in the tensor network is a data structure having an order and a dimension, wherein the order refers to that a tensor is connected to how many edges, and may be represented by different exponential indexes (for example, i, j, k, l); and the dimension refers to that each index many have several possible accesses. Under the framework of quantum computing, the dimension of the tensor is a 4-component density operator, and the value thereof isΠ={|0><0]|,|0><1|,|1><0|,|1><1]}. Therefore, for a k-order tensor, we can use a one-dimensional array for storage, and it is necessary to store 4k complex numbers.

A method for constructing a tensor network has been disclosed in the related art: for an input state p within a single quantum bit, the tensor of which is _σ=tr(ρ·σ) (wherein σ ∈ Π); for an operation gate within a single quantum bit, the tensor of which is T_(σ,τ)=tr(τ^+ G(σ)); for an operation gate with two quantum bits, the tensor of which is T_(σ_1,σ_2 τ_1,τ_2)=tr((τ_1⊗τ_2)^+ G(σ_1⊗σ_2)); and the tensor of a quantum measurement is T_τ=tr(E·τ), wherein E is a POVM element operator, and G is a unitary evolution operator.

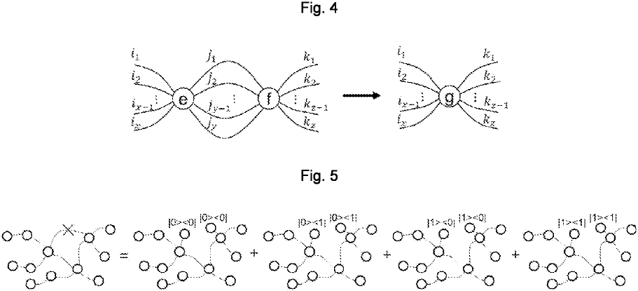

Tensor contraction and merging is a tensor operation, in which two tensors are contracted and merged into one tensor in a manner as shown in FIG. 4. Two connected tensors have an inner edge and an open edge, and the tensor contraction and merging is to contract the inner edge and merge the two vertices into one. As shown in FIG. 4, for two tensors e and f, e is an (x+y)-order tensor, f is a (y+z)-order tensor, and an (x+z)-order tensor may be obtained after contraction and merging. The operation process is as follows:

$${g}_{{i}_{1} , {i}_{2} , … {i}_{x} , {k}_{1} , {k}_{2} , … {k}_{z}} = {\sum }_{{j}_{1} , {j}_{2} , … {j}_{y}} {e}_{{i}_{1} , {i}_{2} , … {i}_{x} , {j}_{1} , {j}_{2} , … {j}_{y}} . {f}_{{j}_{1} , {j}_{2} , … {j}_{y} , {k}_{1} , {k}_{2} , … {k}_{z}}$$

After the contraction and merging operation of a plurality of tensors in the tensor network is completed in sequence, a zero-order tensor is obtained, and the zero-order tensor is a probability amplitude corresponding to the POVM (positive operator value measurement) element.

The maximum memory overhead of the contraction and merging of the tensor network depends on the tensor of the maximum order in the contraction and merging process. Generally, with the progress of the contraction and merging of the tensor network, the maximum order of an intermediate process tensor will first increase and then decrease. For example, after the contraction and merging operation of a (3+2)-order tensor and a (2+3)-order tensor, a (3+3)-order tensor is obtained. The maximum order of the intermediate tensor is related to the contraction and merging sequence of the tensors, each contraction and merging sequence corresponds to tree decomposition of one graph, and an optimal elimination sequence is tree decomposition with the minimum tree width.

It is set that G=(V,E) is an undirected graph, a node subset of the graph G constitutes a bag (bag), which is denoted as Bᵢ, and the tree decomposition of the graph G is a tree T, which is composed of the bag Bᵢ. One tree decomposition of the graph G may be represented as the mapping of a vertex V(G) of the graph to the bag Bi, and meets the following conditions:
(1) U_{i∈v(T)}Bᵢ = V(G), a node set in the bag may cover the node set of the graph G;
(2) ∀{u, v} ∈ E(G), ∃i ∈ V(T), so that {u, v} ∈ Bᵢ, that is, two nodes of each edge in the graph G are contained in a certain node in the tree decomposition at the same time; and
(3) if k in the tree T appears on a path from i to j, then Bᵢ ∩ Bⱼ = Bₖ.

With regard to the tree decomposition T, the width of which is defined as max(|B_{ν∈v(T)}| - 1). The tree decomposition of a graph G is not unique, and the tree width of the graph G refers to a minimum value of the width in all possible tree decompositions of the graph G, which is denoted as tw(G). How to compute the tree width and the tree decomposition is an NP (Non-deterministic polynominal, non-deterministic polynominal) problem, but open-source software may be applied in actual computing, such as QuickBb. In fact, the time overheads of the contraction and merging of the tensor network are also related to the tree width.

On the basis of the specific means of the above tensor contraction and merging, the problem of computing space complexity and application requirements on a distributed computing system are met, the embodiments of the present invention specifically propose a tensor network contraction and merging algorithm, which better adapts to the distributed computing system and reduces the tree width: rather than eliminating a vertex, but eliminating an edge. In the tensor network, each edge has four different indexes: |0><0|, |0><1|, |1><0| and |1><1|. As shown in FIG. 5, we can cut off this edge to generate four sub-graphs with different initializations; and each sub-graph is added after being subjected to contraction and merging, and the result is consistent with the result of an original graph after being subjected to contraction and merging. The theoretical computing is shown as follows:

$$\begin{matrix}\text{p} = {\sum }_{… i , j , k , l , o , p , q …} … {T}_{i , j , k , l}^{m} {T}_{i , o , p , q}^{n} … \\ = {\sum }_{… j , k , l , o , p , q …} … {T}_{\left|0 > < 0\right| , j , k , l}^{m} {T}_{\left|0 > < 0\right| , o , p , q}^{n} … + \\ {\sum }_{… j , k , l , o , p , q …} … {T}_{\left|0 > < 1\right| , j , k , l}^{m} {T}_{\left|0 > < 1\right| , o , p , q}^{n} … + \\ {\sum }_{… j , k , l , o , p , q …} … {T}_{\left|1 > < 0\right| , j , k , l}^{m} {T}_{\left|1 > < 0\right| , o , p , q}^{n} … + \\ {\sum }_{… j , k , l , o , p , q …} … {T}_{\left|1 > < 1\right| , j , k , l}^{m} {T}_{\left|1 > < 1\right| , o , p , q}^{n} …\end{matrix}$$

This fact means that the contraction and merging of different sub-graphs may be computed on different cores, respectively, thereby realizing distributed contraction and merging of the tensor network. At the same time, it must be noted that, the sub-graph subjected to edge cutting has a smaller tree width, which means that the sub-graph contraction and merging have smaller memory occupancy and lower time algorithm complexity. For example, if the tree width of the original undirected graph in FIG. 4 is 3, and the tree width of the sub-graph generated after edge cutting is 1. Actually, if necessary, a plurality of edges may be completely eliminated, and the greater the number of eliminated edges is, the smaller the tree width of the generated sub-graph is, and then the greater the number of generated sub-graphs is. If m edges are eliminated, the number of generated sub-graphs is 4^{m}. The embodiments of the present invention aim to generate sub-graphs of which the number is close to that of available distributed processor threads; and if the number of generated sub-graphs is not greater than the number of computing cores, then the contraction and merging of different sub-graphs may be computed by using different cores, and if the number of sub-graphs is greater than the number of computing cores, then a serial manner is required.

This will bring a plurality of preferred technical effects. In the embodiments of the present invention, it is only necessary to collect the contraction and merging result (i.e., only a complex number) of each sub-process in a main process, and there is no need for sub-processes, which perform a complete vertical operation, to communicate with each other, then the communication between super-computing nodes will be reduced to be very low, and therefore, the bottleneck is no longer a bottleneck. At the same time, the structure of each sub-graph obtained by the contraction and merging of each process is completely consistent, so that the used computing time is also consistent, thereby being free of the situation in which some processes are idle, and then the utilization rate of the distributed computing system is also fully improved.

At this time, the only remaining problem is to determine how to cut edges. The tree widths of sub-graphs generated by eliminating different edges differ a lot, therefore, it is crucial to improving the performance of the algorithm by finding a set of optimal eliminated edges. Search for the optimal set itself is an NP problem, and when the scale of the graph is large, it is obviously impossible to find the set of optimal eliminated edges by means of exhaustion within a limited time. As an approximate alternative, the embodiments of the present invention propose a heuristic algorithm-based strategy for finding the optimal eliminated edges.

First, the genetic algorithm is initialized, an iteration counter is set to be t=0, the maximum number of iterations T is set, and a population P is initialized, wherein the population P has N individuals, and each individual is a set of M edges (eliminated), which are randomly selected from an undirected graph.

The following steps are then repeated:

Step 1: individual evaluation. The tree widths of corresponding graphs of the N individuals in the population P are computed and sorted.

Step 2: cross operation (chromosome variation). In addition to the individual with the minimum tree width, every two adjacent individuals are crossed, the cross mode is that the latter [N] elements in the two sets are exchanged, and if there are repeated elements in the crossed set, elements, which do not exist in one set, are randomly generated.

Step 3: variation operation (gene mutation). An individual except the optimal individual is selected from the population for variation, an edge is randomly selected from the set of the individual edges, and then an edge, which does not exist in the set, is randomly generated then.

Step 4: add 1 to the iteration counter. t=t+1, Until (until) t >T.

Finally, at the end of the circulation, the individuals in the population are evaluated, and an optimal individual is returned to cut the edges.

It can be seen from the above-mentioned embodiments that, the distributed quantum computing simulation method provided in the embodiments of the present invention has technical effects as follows: by means of the technical solutions of converting the quantum circuit to be simulated into the tensor network that is represented by the undirected graph, and segmenting the undirected graph into the plurality of sub-graphs by using the genetic algorithm that is based on the operation resources of the distributed system; respectively performing, on the sub-process nodes, tensor contraction and merging on the plurality of sub-graphs for the connected tensors until only one tensor is left, so as to finally obtain the zero-order tensors of the plurality of sub-graphs at the same time; and acquiring and superposing the zero-order tensors of the plurality of sub-graphs from the sub-process nodes at the same time, so as to determine the zero-order tensor of the undirected graph, and using the zero-order tensor of the undirected graph as the probability amplitude of the positive operator value measurement element, so as to perform quantum computing simulation, density matrix-based single-amplitude strategy quantum computing simulation can be performed on the distributed computing system, thereby improving the universality and usability of single-amplitude strategy quantum computing simulation.

It should be particularly pointed out that, in various embodiments of the foregoing distributed quantum computing simulation method, the various steps may be exchanged, replaced, increased and decreased, therefore these reasonable permutation and combination transformations should also fall within the protection scope of the present invention with respect to the distributed quantum computing simulation method, and the protection scope of the present invention should not be limited to the embodiments.

Based on the above objectives, a second aspect of the embodiments of the present invention provides an embodiment of a distributed quantum computing simulation apparatus, which is capable of performing density matrix-based single-amplitude strategy quantum computing simulation on a distributed computing system. The distributed quantum computing simulation apparatus includes a main process node and a plurality of sub-process nodes, wherein:
the main process node is configured to convert a quantum circuit to be simulated into a tensor network that is represented by an undirected graph, and segment the undirected graph into a plurality of sub-graphs by using a genetic algorithm that is based on operation resources of a distributed system;
the plurality of sub-process nodes are configured to respectively perform tensor contraction and merging on the plurality of sub-graphs for connected tensors until only one tensor is left, so as to finally obtain zero-order tensors of the plurality of sub-graphs at the same time; and
the main process node is further configured to acquire and superpose the zero-order tensors of the plurality of sub-graphs at the same time, so as to determine a zero-order tensor of the undirected graph, and use the zero-order tensor of the undirected graph as a probability amplitude of a positive operator value measurement element, so as to perform quantum computing simulation.

In some embodiments, the main process node segmenting the undirected graph into the plurality of sub-graphs by using the genetic algorithm that is based on the operation resources of the distributed system includes:
determining, on the basis of the operation resources of the distributed system, the number of times for segmenting the undirected graph, such that the exponential power of the number of times for segmentation with 4 as a base approaches to the number of available sub-processes;
determining, on the basis of the number of times for segmentation and by using the genetic algorithm, an edge set for segmenting the undirected graph;
cutting an edge in the edge set from the undirected graph, and generating two new vertices at the cut-off position;
assigning one of 4-component density operators {|0><0|, |0><1|, |1><0|, |1><1|} to the two new vertices as the tensors of the two new vertices; and
generating, on the basis of different assignments of the density operators of the tensors of the two new vertices, all possible combinations as the plurality of sub-graphs, wherein the number of sub-graphs is the exponential power of the number of times for segmentation with 4 as the base.

In some embodiments, the main process node determining, on the basis of the number of times for segmentation and by using the genetic algorithm, the edge set for segmenting the undirected graph includes:
constructing a determined number of undirected graphs as individuals to form an undirected graph population, randomly selecting, from the undirected graphs, edges in the number of times for segmentation, so as to generate the edge set, and the following steps are further included:
   computing the widths of undirected graph trees of all individuals in the population, and sorting all individuals according to the size of the widths of the undirected graph trees;
   enabling all individuals, except the individual with the minimum width of the undirected graph tree, to exchange some edges in the edge set in a two-by-two adjacent manner, so as to perform chromosome variation;
   replacing one edge randomly selected from an edge set, which is randomly selected from all individuals except the individual with the minimum width of the undirected graph tree, with another randomly selected edge, so as to perform gene mutation;
   in response to the occurrence of repeated edges in the edge set, randomly selecting edges, which do not exist in the edge set, so as to replace the repeated edges; and
   repeatedly and circularly performing the steps until the number of cycles exceeds a predetermined maximum number of iterations, and returning optimal individuals in the population as the edge set.

It can be seen from the above-mentioned embodiments that, the distributed quantum computing simulation apparatus provided in the embodiments of the present invention has technical effects as follows: by means of the technical solutions of converting the quantum circuit to be simulated into the tensor network that is represented by the undirected graph, and segmenting the undirected graph into the plurality of sub-graphs by using the genetic algorithm that is based on the operation resources of the distributed system; respectively performing, on the sub-process nodes, tensor contraction and merging on the plurality of sub-graphs for the connected tensors until only one tensor is left, so as to finally obtain the zero-order tensors of the plurality of sub-graphs at the same time; and acquiring and superposing the zero-order tensors of the plurality of sub-graphs from the sub-process nodes at the same time, so as to determine the zero-order tensor of the undirected graph, and using the zero-order tensor of the undirected graph as the probability amplitude of the positive operator value measurement element, so as to perform quantum computing simulation, density matrix-based single-amplitude strategy quantum computing simulation can be performed on the distributed computing system, thereby improving the universality and usability of single-amplitude strategy quantum computing simulation.

It should be particularly pointed out that, the embodiment of the distributed quantum computing simulation apparatus uses the embodiment of the distributed quantum computing simulation method to specifically describe the working process of each module, and those skilled in the art may readily think that these modules are applied to other embodiments of the distributed quantum computing simulation method. Of course, since the various steps in the embodiment of the distributed quantum computing simulation method may be exchanged, replaced, increased and decreased, these reasonable permutation and combination transformations should also fall within the protection scope of the present invention with respect to the distributed quantum computing simulation apparatus, and the protection scope of the present invention should not be limited to the embodiments.

The above descriptions are exemplary embodiments disclosed in the present invention, but it should be noted that various changes and modifications may be made without departing from the scope of the embodiments of the present invention defined by the claims. The functions, steps and/or actions of the method claims according to the disclosed embodiments described herein need not be performed in any particular order. In addition, although the elements disclosed in the embodiments of the present invention may be described or claimed in an individual form, it may be understood that there are a plurality of elements, unless explicitly limited to be singular.

Those ordinary skilled in the art to which the present invention belongs should understand that, the discussion of any of the above embodiments is merely exemplary, and is not intended to imply that the scope (including the claims) disclosed in the embodiments of the present invention is limited to these examples; and in the idea of the embodiments of the present invention, the technical features in the above embodiments or different embodiments may also be combined with each other, there are many other changes in different aspects of the embodiments of the present invention as described above, and are not provided in detail for the sake of brevity. Therefore, any omissions, modifications, equivalent replacements, improvements, and the like, made within the spirit and principles of the embodiments of the present invention, shall fall within the protection scope of the embodiments of the present invention.

What is claimed is:

1. A distributed quantum computing simulation method, comprising:
converting a quantum circuit to be simulated into a tensor network that is represented by an undirected graph, and segmenting the undirected graph into a plurality of sub-graphs by using a genetic algorithm that is based on operation resources of a distributed system;
respectively performing, on sub-process nodes, tensor contraction and merging on the plurality of sub-graphs for connected tensors until only one tensor is left, so as to finally obtain zero-order tensors of the plurality of sub-graphs at the same time; and
acquiring and superposing the zero-order tensors of the plurality of sub-graphs from the sub-process nodes at the same time, so as to determine a zero-order tensor of the undirected graph, and using the zero-order tensor of the undirected graph as a probability amplitude of a positive operator value measurement element, so as to perform quantum computing simulation.

2. The method according to claim 1, wherein the step of converting the quantum circuit to be simulated into the tensor network that is represented by the undirected graph, comprises:
converting, by using an trace operation, an input state, an operation gate and a measurement of a quantum bit in the quantum circuit into tensors, and determining the tensors to be vertexes in the undirected graph; and
determining connection relationships among the input state, the operation gate and the measurement of the quantum bit in the quantum circuit to be connected edges between corresponding vertices in the undirected graph.

3. The method according to claim 1, wherein the step of segmenting the undirected graph into the plurality of sub-graphs by using the genetic algorithm that is based on the operation resources of the distributed system, comprises:
determining, on the basis of the operation resources of the distributed system, the number of times for segmenting the undirected graph, such that the exponential power of the number of times for segmentation with 4 as a base approaches to the number of available sub-processes;
determining, on the basis of the number of times for segmentation and by using the genetic algorithm, an edge set for segmenting the undirected graph;
cutting an edge in the edge set from the undirected graph, and generating two new vertices at the cut-off position;
assigning one of 4-component density operators {|0><0|, |0><1|, |1><0|, |1><1|} to the two new vertices as the tensors of the two new vertices; and
generating, on the basis of different assignments of the density operators of the tensors of the two new vertices, all possible combinations as the plurality of sub-graphs, wherein the number of sub-graphs is the exponential power of the number of times for segmentation with 4 as the base.

4. The method according to claim 3, wherein the step of determining, on the basis of the number of times for segmentation and by using the genetic algorithm, the edge set for segmenting the undirected graph, comprises:
constructing a determined number of undirected graphs as individuals to form an undirected graph population, randomly selecting, from the undirected graphs, edges in the number of times for segmentation, so as to generate the edge set.

5. (canceled)

6. The method according to claim 1, wherein the step of respectively performing, on the sub-process nodes, tensor contraction and merging on the plurality of sub-graphs for the connected tensors until only one tensor is left, so as to finally obtain the zero-order tensors of the plurality of sub-graphs at the same time, comprises:
respectively performing, by the sub-process nodes, tensor contraction and merging for different nodes in the plurality of sub-graphs in sequence by using the same tensor contraction and merging sequence, consuming the same computing resources within a unit computing time, and enabling the sub-process nodes with the same computing capability to obtain the zero-order tensors of the plurality of sub-graphs at the same time.

7. The method according to claim 1, wherein the step of converting the quantum circuit to be simulated into the tensor network that is represented by the undirected graph, and segmenting the undirected graph into the plurality of sub-graphs by using the genetic algorithm that is based on the operation resources of the distributed system; and the step of acquiring and superposing the zero-order tensors of the plurality of sub-graphs from the sub-process nodes at the same time, so as to determine the zero-order tensor of the undirected graph, and using the zero-order tensor of the undirected graph as the probability amplitude of the positive operator value measurement element, so as to perform quantum computing simulation, are all performed on a main process node of the distributed system.

8. A distributed quantum computing simulation apparatus, comprising a main process node and a plurality of sub-process nodes, wherein:
the main process node is configured to convert a quantum circuit to be simulated into a tensor network that is represented by an undirected graph, and segment the undirected graph into a plurality of sub-graphs by using a genetic algorithm that is based on operation resources of a distributed system;
the plurality of sub-process nodes are configured to respectively perform tensor contraction and merging on the plurality of sub-graphs for connected tensors until only one tensor is left, so as to finally obtain zero-order tensors of the plurality of sub-graphs at the same time; and
the main process node is further configured to acquire and superpose the zero-order tensors of the plurality of sub-graphs at the same time, so as to determine a zero-order tensor of the undirected graph, and use the zero-order tensor of the undirected graph as a probability amplitude of a positive operator value measurement element, so as to perform quantum computing simulation.

9. The apparatus according to claim 8, wherein the main process node is further configured to:
determine, on the basis of the operation resources of the distributed system, the number of times for segmenting the undirected graph, such that the exponential power of the number of times for segmentation with 4 as a base approaches to the number of available sub-processes;
determine, on the basis of the number of times for segmentation and by using the genetic algorithm, an edge set for segmenting the undirected graph;
cut an edge in the edge set from the undirected graph, and generate two new vertices at the cut-off position;
assigning one of 4-component density operators {|0><0|, |0><1|, |1><0|, |1><1|} to the two new vertices as the tensors of the two new vertices; and
generate, on the basis of different assignments of the density operators of the tensors of the two new vertices, all possible combinations as the plurality of sub-graphs, wherein the number of sub-graphs is the exponential power of the number of times for segmentation with 4 as the base.

10. The apparatus according to claim 9, wherein the main process node is further configured to:
constructing a determined number of undirected graphs as individuals to form an undirected graph population, randomly select, from the undirected graphs, edges in the number of times for segmentation, so as to generate the edge set.

11. The apparatus according to claim 10, wherein the main process node is further configured to:
enable all individuals, except the individual with the minimum width of the undirected graph tree, to exchange some edges in the edge set in a two-by-two adjacent manner, so as to perform chromosome variation;
replace one edge randomly selected from an edge set, which is randomly selected from all individuals except the individual with the minimum width of the undirected graph tree, with another randomly selected edge, so as to perform gene mutation;
in response to the occurrence of repeated edges in the edge set, randomly select edges, which do not exist in the edge set, so as to replace the repeated edges; and
repeatedly and circularly perform the steps until the number of cycles exceeds a predetermined maximum number of iterations, and return optimal individuals in the population as the edge set.

12. The apparatus according to claim 10, wherein the main process node is further configured to:
respectively determine decomposition widths of the corresponding trees on the basis of respective structures of the plurality of trees; and
determine the width of the undirected graph tree on the basis of a minimum value of the decomposition widths of the plurality of trees.

13. The apparatus according to claim 10, wherein the sub-process nodes are configured to respectively perform, by the sub-process nodes, tensor contraction and merging for different nodes in the plurality of sub-graphs in sequence by using the same tensor contraction and merging sequence, consume the same computing resources within a unit computing time, and enable the sub-process nodes with the same computing capability to obtain the zero-order tensors of the plurality of sub-graphs at the same time.

14. The method according to claim 4, further comprising:
computing the widths of undirected graph trees of all individuals in the undirected graph population, and sorting all individuals according to the size of the widths of the undirected graph trees;
enabling all individuals, except the individual with the minimum width of the undirected graph tree, to exchange some edges in the edge set in a two-by-two adjacent manner, so as to perform chromosome variation;
replacing one edge randomly selected from an edge set, which is randomly selected from all individuals except the individual with the minimum width of the undirected graph tree, with another randomly selected edge, so as to perform gene mutation;
in response to the occurrence of repeated edges in the edge set, randomly selecting edges, which do not exist in the edge set, so as to replace the repeated edges; and
repeatedly and circularly performing the steps until the number of cycles exceeds a predetermined maximum number of iterations, and returning optimal individuals in the population as the edge set.

15. The method according to claim 14, wherein the step of computing the width of the undirected graph tree, comprises:
performing tree decomposition on the undirected graph on the basis of all different tension contraction and merging sequences, so as to obtain a plurality of trees;
respectively determining decomposition widths of the corresponding trees on the basis of respective structures of the plurality of trees; and
determining the width of the undirected graph tree on the basis of a minimum value of the decomposition widths of the plurality of trees.

16. The method according to claim 1, the step of respectively performing, on sub-process nodes, tensor contraction and merging on the plurality of sub-graphs for connected tensors comprising:
contracting two inner edges of two connected tensors and merging two vertices of the two connected tensors into one, wherein each of the two connected tensors have an inner edge and an open edge.

17. The method according to claim 1, further comprising:
respectively computing the contraction and merging of different sub-graphs on different cores of distributed processor threads, to realize distributed contraction and merging of the tensor network.

18. The method according to claim 17, further comprising:
in response to the number of generated sub-graphs is not greater than the number of computing cores of distributed processor threads, performing the contraction and merging of different sub-graphs by using different cores;
in response to the number of sub-graphs is greater than the number of computing cores of distributed processor threads, performing the contraction and merging of different sub-graphs by a serial manner.

19. The method according to claim 1, wherein the structure of each sub-graph obtained by the contraction and merging of each process is completely consistent, and used computing time of each sub-graph is consistent.

20. The method according to claim 1, wherein the tensor network is formed by connecting different tensors via topology.

21. The method according to claim 1, wherein the method is capable of performing density matrix-based single-amplitude strategy quantum computing simulation on a distributed computing system.
